(19) United States
(12) Patent Application Publication
(10) Pub. No.: US 2006/0039200 A1
(43) Pub. Date: Feb. 23, 2006

(54) NON-VOLATILE MEMORY CELL, FABRICATION METHOD AND OPERATING METHOD THEREOF

(76) Inventors: Ching-Sung Yang, Hsinchu City (TW); Wei-Zhe Wong, Tainan City (TW); Chih-Chen Cho, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,031

(22) Filed: Mar. 17, 2005

(30) Foreign Application Priority Data
Aug. 20, 2004 (TW) 93125069

(51) Int. Cl. G11C 7/10

(52) U.S. Cl. 365/189.01

(57) ABSTRACT

A non-volatile memory including a plurality of memory units is provided. Each of the memory units includes a first memory cell and a second memory cell. The first memory cell is disposed over the substrate. The second memory cell is disposed next to the sidewall of the first memory cell and over the substrate. The first memory cell includes a first gate disposed over the substrate, a first composite dielectric layer disposed between the first gate and the substrate. The second memory cell includes a second gate disposed over the substrate and a second composite dielectric layer disposed between the second gate and the substrate and between the second gate and the first memory cell. Each of the first and second composite dielectric layers includes a bottom dielectric layer, a charge-trapping layer and a top dielectric layer.

### CROSS-REFERENCE TO RELATED APPLICATION

This application claims the priority benefit of Taiwan application serial no. 93125069, filed Aug. 20, 2004.

### BACKGROUND OF THE INVENTION

1. Field of the Invention

The present invention relates to a semiconductor memory device, and more particularly to a non-volatile memory, a fabrication method and an operating method thereof.

2. Description of the Related Art

Among various types of non-volatile memories, electrically erasable programmable read-only memories (EEPROMs) has the advantage that it can be written, read and erased repeatedly and the stored data is valid when power is off. Accordingly, EEPROMs have been widely used in personal computers and electronic devices.

The floating gate and control gate of conventional EEPROM is typically made of doped polysilicon. To avoid over-erasing the conventional EEPROM and data disturbance therefrom, a select gate is disposed on substrate beside the control gate and the floating gate so as to form a split-gate structure.

In the conventional EEPROM, alternatively, a charge-trapping layer is used instead of the polysilicon floating gate. The material of charge-trapping layer can be silicon nitride. Usually, the nitride charge-trapping layer is disposed between two silicon oxide layers to form an oxide-nitride-oxide (ONO) composite layer. The device formed is usually called a silicon/silicon oxide/silicon nitride/silicon oxide/silicon (SONOS) device. For example, one SONOS device with a split-gate structure is disclosed in the U.S. Pat. No. 5,930,631.

However, the above SONOS device with the split-gate structure requires a lot of space and therefore the size of the memory is large. Accordingly, the EEPROM with the split-gate structure is larger than that with the stacked-gate structure, and the goal of forming a high-density memory cannot be achieved.

### SUMMARY OF THE INVENTION

Accordingly, the present invention is directed to a non-volatile memory, a fabrication method and an operating method thereof that can increase memory cell density and device performance.

The present invention is directed to a non-volatile memory, a fabrication method and an operating method thereof capable of increasing the capacity of the memory, and reducing the manufacturing costs by the simple procedures.

The present invention provides a non-volatile memory unit including a first memory cell and a second memory cell. The first memory cell and the second memory cell are separated by a first insulation spacer disposed on the sidewall of the first memory cell. The first memory cell includes a first gate disposed on the substrate, and a first composite dielectric layer disposed between the first gate and the substrate. The first composite dielectric layer includes a first bottom dielectric layer, a first charge-trapping layer and a first top dielectric layer. The second memory cell includes a second gate disposed over the substrate and a second composite dielectric layer disposed between the second gate and the substrate. The second composite dielectric layer includes a second bottom dielectric layer, a second charge-trapping layer and a second top dielectric layer.

The present invention further provides a nonvolatile memory including a cell column constituted by a plurality of the non-volatile memory units. The non-volatile memory units are connected in series and separated by a plurality of second insulation spacers. The nonvolatile memory further includes a selecting unit disposed on one side of the cell column. The selecting unit includes a third gate, a third composite dielectric layer disposed between the third gate and the substrate. The third composite dielectric layer includes a third bottom dielectric layer, a third charge-trapping layer and a third top dielectric layer. The nonvolatile memory further includes a third insulation spacer disposed on a sidewall of the selecting unit, wherein the third insulation spacer is disposed between the selecting unit and the cell column. The nonvolatile memory further includes a source region disposed on the other side of the cell column and a drain region disposed in the substrate adjacent to the selecting unit.

The present invention further provides a non-volatile memory including a memory cell array constituted by a plurality of first memory cells and a plurality of second memory cells; and a plurality of selecting units, each disposed on one side of each column of the memory cell array respectively. In each column, the selecting unit and the plurality of first memory cells are arranged to form a plurality of gaps and each of the plurality of second memory cells stuffs up a different one of the gaps respectively. The nonvolatile memory further includes a plurality of first doped regions, each disposed on the other side of each column of the memory cell array respectively; a plurality of second doped regions, each disposed adjacent to each of the plurality of selecting units respectively; a plurality of word lines; a plurality of bit lines, wherein each intersection of the plurality of word lines and each of the plurality of bit lines is corresponding to a different one of the plurality of first memory cells or the plurality of second memory cells; a plurality of selecting lines, each connected to a different row of the plurality of selecting units; and a plurality of common lines, each connected to a different row of the plurality of first doped regions.

The present invention also provides an operating method for the non-volatile memory described above. In the method, while programming a selected memory cell, 0V is applied to a selected bit line, a first voltage is applied to unselected bit lines, a second voltage is applied to a selected word line, which is closed to the word line coupled to the selected memory cell and adjacent to the drain region, a third voltage is applied to unselected word lines and selecting lines, and a fourth voltage is applied to a source line so as to program the selected memory cell by source-side injection (SSI) method.

In order to read the non-volatile memory described above, 0V is applied to the selected bit line, a fifth voltage is applied to the unselected bit lines, a sixth voltage is applied to the word line coupled to the selected memory cell, a seventh voltage is applied to the unselected word lines and the selecting line, and an eighth voltage is applied to the source line so as to read the selected memory cell.

Then, a ninth voltage is applied to the selected bit line, 0V is applied to the unselected bit lines, a tenth voltage is applied to the word line coupled to the selected memory cell, an eleventh voltage is applied to all unselected word lines between the word line coupled to the selected memory cell and the drain region, and applied to the selecting line, 0V is applied to all unselected word lines between the word line coupled to the selected memory cell and the source region so as to erase the selected memory cells by hot-hole injection method.

The present invention also provides another erasing method for the nonvolatile memory described above. In the method, a twelfth voltage is applied to the word lines and a thirteenth voltage is applied to the substrate so as to erase the whole memory cell array by FN tunneling method.

The present invention also provides a method of fabricating a non-volatile memory. The method includes the steps of providing a substrate; forming a plurality of gate structures over the substrate, each of the gate structures comprising a first composite dielectric layer, a first gate, and a cap layer, wherein every two of the plurality of gate structures are separated by a gap; forming insulation spacers on sidewalls of the gate structures; forming a second composite dielectric layer over the substrate; forming a conductive layer over the substrate; removing a portion of the conductive layer to form a plurality of second gates in the gaps between the gate structures, the second gates and the gate structures constituting a memory cell column; and forming a source region and a drain region in the substrate respectively adjacent to two sides of the memory cell column.

The above and other features of the present invention will be better understood from the following detailed description of the embodiments of the invention that is provided in combination with the accompanying drawings.

### BRIEF DESCRIPTION OF THE DRAWINGS

FIG. 1A is a top view of a non-volatile memory according to an embodiment of the present invention.

FIG. 1B is a cross-sectional view of the non-volatile memory along line A-A′ in FIG. 1A.

FIG. 1C is a cross-sectional view showing a selecting unit and a memory unit according to an embodiment of the present invention.

FIG. 2 is a circuit diagram of the nonvolatile memory according to the present invention.

FIG. 3A is a schematic drawing showing a programming operation according to an embodiment of the present invention.

FIG. 3B is a schematic drawing showing a reading operation according to the embodiment of the present invention.

FIG. 3C is a schematic drawing showing a reading operation of a non-volatile memory according to an embodiment of the present invention.

FIG. 3D is a schematic drawing showing an erasing operation of a non-volatile memory according to an embodiment of the present invention.

FIG. 3E is a schematic drawing showing an erasing operation of a non-volatile memory according to another embodiment of the present invention.

FIG. 3F is a schematic drawing showing an erasing operation of a non-volatile memory according to still another embodiment of the present invention.

FIG. 3G is a schematic drawing showing an erasing operation of a non-volatile memory according to yet another embodiment of the present invention.

FIGS. 4A-4E are cross-sectional drawings showing a progression of a method of fabricating a non-volatile memory along A-A′ of FIG. 2A according to an embodiment of the present invention.

### DESCRIPTION OF THE EMBODIMENTS

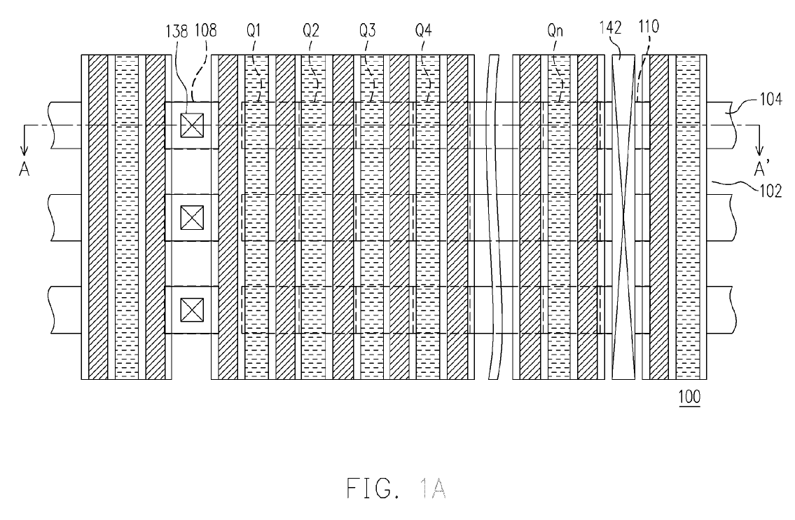

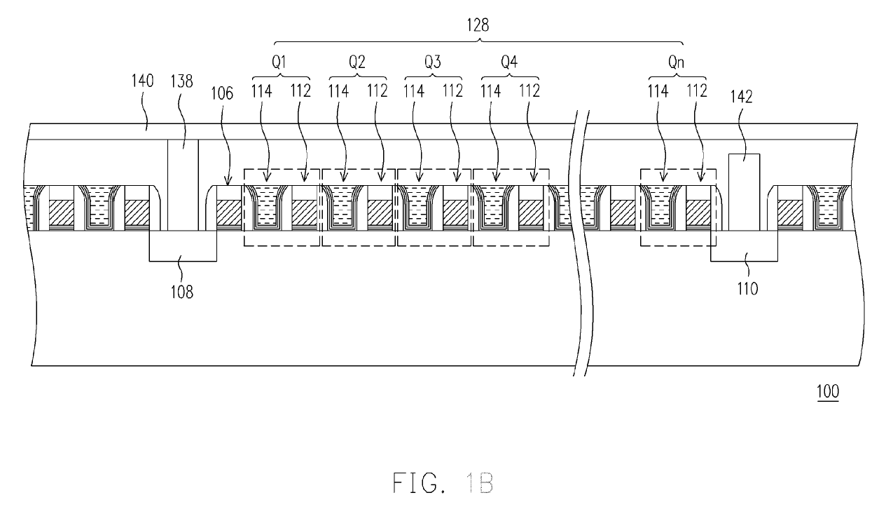

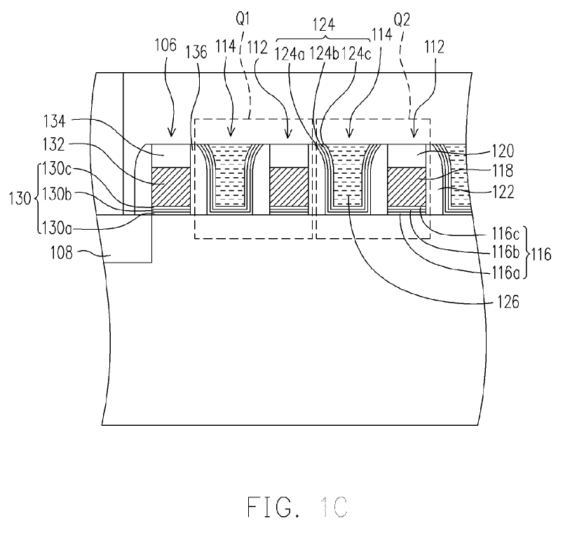

FIG. 1A is a top view of a non-volatile memory according to an embodiment of the present invention. FIG. 1B is a cross-sectional view of the non-volatile memory along line A-A′ of FIG. 1A. FIG. 1C is a cross-sectional view showing a selecting unit and a memory unit according to an embodiment of the present invention.

Referring to FIGS. 1A-1C, the non-volatile memory of the present invention includes at least a substrate 100, a device isolation structure 102, an active area 104, a plurality of memory units Q1-Qn, a selecting unit 106, a drain region 108 and a source region 110.

The substrate 100 can be an N-type or a P-type silicon substrate. The device isolation structure 102 is formed in the substrate 100 to define the active area 104.

The memory units Q1-Qn are disposed over the substrate 100. Each of the memory units Q1-Qn is constituted by a memory cell 112 and a memory cell 114.

The memory cell 112 is disposed over the substrate 100 and includes a composite dielectric layer 116, a gate 118, a cap layer 120 and an insulation spacer 122. The gate 118 is disposed over the substrate 100. The composite dielectric layer 116 is disposed between the gate 118 and the substrate 100. The composite dielectric layer 116 includes a bottom dielectric layer 116a, a charge-trapping layer 116b and a top dielectric layer 116c. The cap layer 120 is disposed over the gate 118. The insulation spacer 122 is disposed on the sidewalls of the gate 118 and the composite dielectric layer 116. Wherein, the material of the bottom dielectric layer 116a can be, for example, silicon oxide. The material of the charge-trapping layer 116b can be silicon nitride. The material of the top dielectric layer 116c can be silicon oxide. The material of the gate 118 can be doped polysilicon. The material of the cap layer 120 can be silicon oxide. The material of the insulation spacer 122 can be silicon oxide or silicon nitride.

The memory cell 114 is disposed adjacent to the memory cell 112 and over the substrate 100. The memory cell 114 may include, for example, the composite dielectric layer 124 and the gate 126. The gate 126 is disposed over the substrate 100. The composite dielectric layer 124 is disposed between the gate 126 and the substrate 100, and between the gate 126 and the memory cell 112. The composite dielectric layer 124, from the substrate 100 and on the sidewall of the memory cell 112, includes the bottom dielectric layer 124a, the charge-trapping layer 124b and the top dielectric layer 124c. Wherein, the material of the bottom dielectric layer 124a can be, for example, silicon oxide. The material of the charge-trapping layer 124b can be silicon nitride. The material of the top dielectric layer 124c can be silicon oxide. The material of the gate 126 can be doped polysilicon. The memory cell 114 is separated from the memory cell 112 by the insulation spacer 122.

The memory units Q1-Qn constitute a memory cell column 128, for example, in the active area 104. The memory cells 112 and 114 are staggered without gaps in between. The memory cell 114 and the memory cell 112 of the memory cell column 128 are separated by the insulation spacer 122. The memory cell columns 128 are separated from each other by the device isolation structure 102.

The selecting unit 106 is adjacent to the edge memory cell 114 of the memory cell column 128. The selecting unit 106 may include, for example, the composite dielectric layer 130, the gate 132, the cap layer 134 and the insulation spacer 136. The gate 132 is disposed over the substrate 100. The composite dielectric layer 130 is disposed between the gate 132 and the substrate 100. The composite dielectric layer 130 includes, from the bottom over substrate 100, the bottom dielectric layer 130a, the charge-trapping layer 130b and the top dielectric layer 130c. The cap layer 134 is disposed over the gate 132. The insulation spacer 136 is formed on the sidewalls of the gate 132 and the composite dielectric layer 130. Wherein, the material of the bottom dielectric layer 130a can be, for example, silicon oxide. The material of the charge-trapping layer 130b can be silicon nitride. The material of the top dielectric layer 130c can be silicon oxide. The material of the gate 132 can be doped polysilicon. The material of the cap layer 134 can be silicon oxide. The insulation spacer 136 can be silicon oxide or silicon nitride. The selecting unit 106 and the edge memory cell 114 of the memory cell column 128 are separated by the insulation spacer 136.

The drain region 108 is disposed in the substrate 100 adjacent to one side of the selecting unit 106 which is not adjacent to the memory cell column 128. The source region 110 is disposed in the other side of the substrate 100 adjacent to the edge memory cell 112 of the memory cell column 128.

The drain region 108 is connected to the bit line 140 via plug 138. The source region 110 is electrically connected to the source line 142.

In the non-volatile memory described above, the memory cell column 128 in the active area 104 is constituted by staggered memory cells 112 and 114. Without gaps between the memory cells 112 and 114 and between the selecting unit 106 and the memory cell 114, the density of the memory cell array is enhanced. Further, because the memory cells 112 and 114 of the memory cell column can store charges, the capacity of the memory is also improved.

In addition, the memory cells 112 and 114 use the charge-trapping layers 110 to store charges, the low gate-coupling ratio is not a concern. With low operating voltage, the memory of the present invention can achieve the desired operating speed.

In addition, the number of the memory cells can be modified according to the requirement. For example, a memory cell column may include 32 to 64 memory cells.

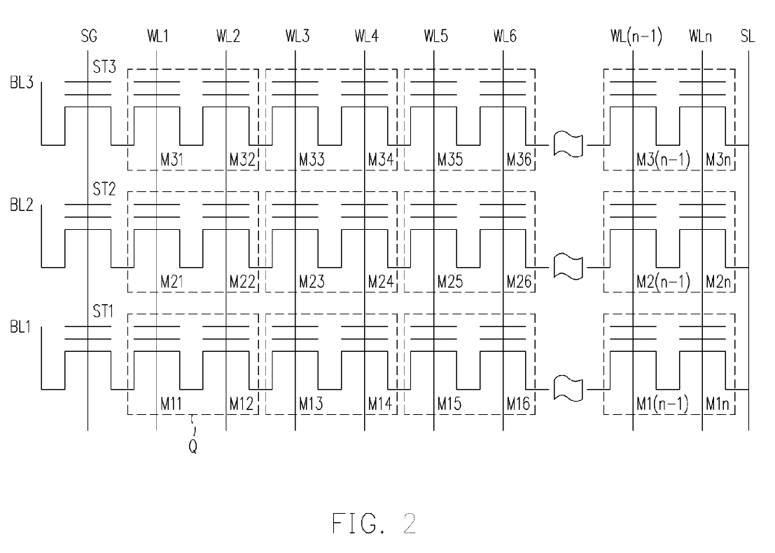

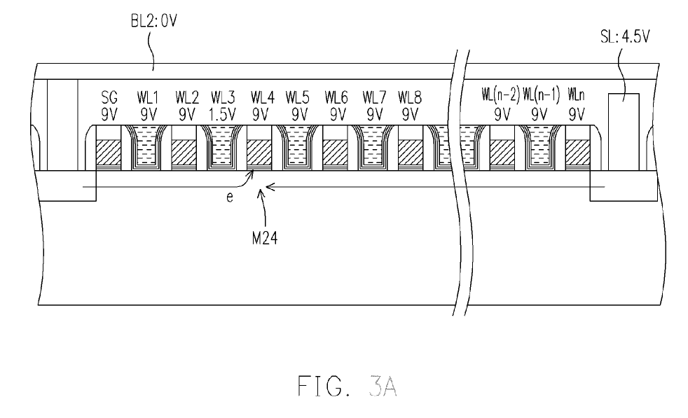

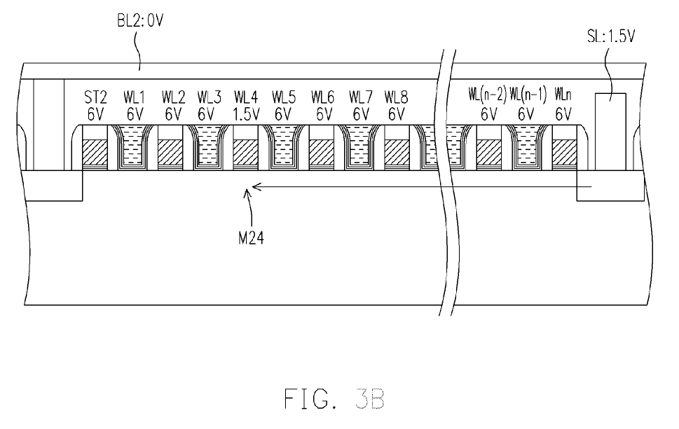

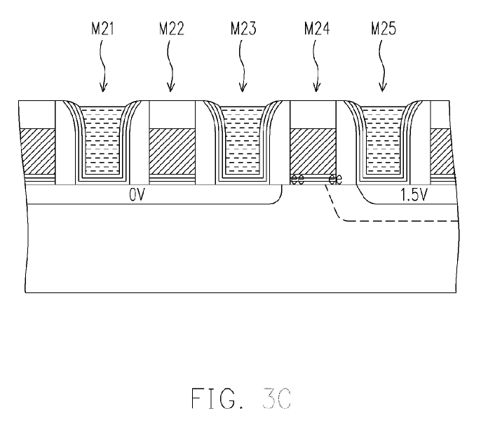

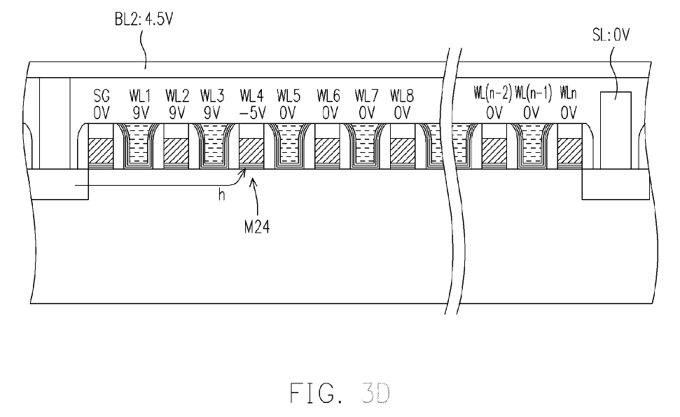

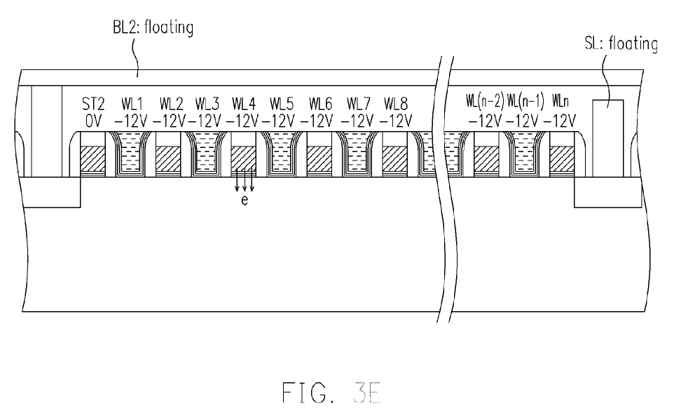

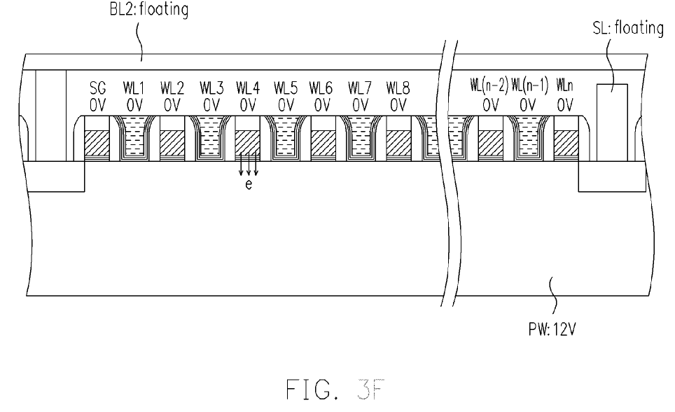

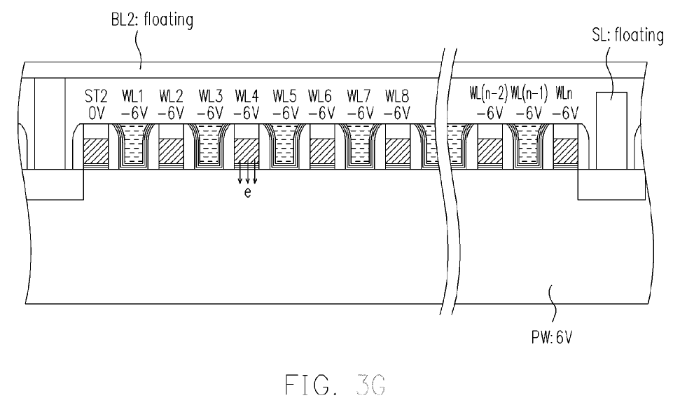

FIG. 2 is a schematic drawing showing a non-volatile memory circuit to describe the operating method according to an embodiment of the present invention. FIG. 3A is a schematic drawing showing a programming operation of a non-volatile memory according to an embodiment of the present invention. FIG. 3B is a schematic drawing showing a reading operation of a non-volatile memory according to an embodiment of the present invention. FIG. 3C is a schematic drawing showing a reading operation of a non-volatile memory according to an embodiment of the present invention. FIG. 3D is a schematic drawing showing an erasing operation of a non-volatile memory according to an embodiment of the present invention. FIG. 3E is a schematic drawing showing an erasing operation of a non-volatile memory according to another embodiment of the present invention. FIG. 3F is a schematic drawing showing an erasing operation of a non-volatile memory according to still another embodiment of the present invention. FIG. 3G is a schematic drawing showing an erasing operation of a non-volatile memory according to yet another embodiment of the present invention.

With reference to FIG. 2, the non-volatile memory includes a plurality of memory cells M11-M3n, a plurality of selecting units ST1-ST3, a selecting line SG, word lines WL1-WLn, and bit lines BL1-BL3.

The memory cells M11-M3n are disposed over the substrate to form an array. The memory cells constitute a memory cell column without gaps. For example, the memory cells M11, M12, M13, . . . , M1n constitute a memory cell column. The M21, M22, M23, . . . , M2n constitute a memory cell column. M31, M32, M33, . . . , M3n constitute a memory cell column.

The selecting units ST1-ST3 are disposed adjacent to an outmost memory cell among the memory cell columns. For example, the selecting unit ST1 is adjacent to the memory cell M11; the selecting unit ST2 is adjacent to the memory cell M21; the selecting unit ST3 is adjacent to the memory cell M31. The selecting line SG connects the gates of the selecting units ST1-ST3 in the same row. The parallel word lines WL1 -WLn connect the gates of the memory cells in the same row. For example, the word line WL1 connects the gates of the memory cells M11, M21 and M31; the word line WL2 connects the gates of the memory cells M13, M23 and M33. Accordingly, the word line WLn connects the gates of the memory cells M1n, M2n and M3n. The parallel bit lines BL1-BL3 connect the drain regions in the same column. The drain regions are disposed in the substrate adjacent to the selecting units ST1-ST3. The source line SL connects the source regions in the same row. The source regions are disposed in the substrate at the other side of the memory cell columns. In the memory cell column, two neighboring memory cells, such as M11 and M12, constitute a memory unit Q. The memory cells M13 and M14 constitute a memory unit. Accordingly, the memory cells M3(n-1) and M3n constitute a memory unit.

With reference to FIGS. 2 and 3A, while a selected memory cell, such as M24, is to be programmed, a voltage of about 0V is applied to the selected bit line BL2, a voltage of about 1.5V is applied to the selected word line WL3, which is adjacent to the selected memory cell M24 near the drain side, and a voltage of about 4.5V is applied to the source line SL. Meanwhile, a voltage of about 3.3V is applied to the unselected bit lines BL1 and BL3, and a voltage of about 9V is applied to the unselected word lines WL1, WL2, WL4-WLn and the selecting line SG. Electrons are injected into the charge-trapping layer of the memory cell M24 by source-side injection (SSI) so as to program the selected memory cell M24. The electrons are localized stored in the charge-trapping layer of the memory cell M24 near the drain side.

According to the programming mode described above, while the selected memory cell is to be programmed, another memory cell that is adjacent to the selected memory cell near the drain side functions as a select gate to make electrons inject into the selected memory cell. For example, while the memory cell M24 is to be programmed, the memory cell M23 serves as a select gate. By reducing the voltage applied to the select gate, i.e. the memory cell M23, electrons are injected into the charge-trapping layer of the selected memory cell M24 in the programming step. That is, according to the embodiment described above, except the memory cells M1n, M2n and M3n only serve as memory cells, the other memory cells M11-M1(n-1), M21-M2(n-1), and M31-M3(n-1) can serve as memory cells or select gates depending on which memory cell is to be programmed.

With reference to FIGS. 2 and 3B, while the selected memory cell M24, is to be read, a voltage of about 0V is applied to the selected bit line BL2, a voltage of about 1.5V is applied to the word line WL4 coupled to the selected memory cell M24 and a voltage of about 1.5V is applied to the source line SL. Meanwhile, a voltage of about 1.5V is applied to the unselected bit lines BL1 and BL3, and a voltage of about 6V is applied to the unselected word lines WL1-WL3, WL5-WLn and the selecting line SG. Under such a circumstance, the channel under the selected memory cell M24 is turned off and with low channel current if negative charges are stored in its charge-trapping layer. On the other hand, the channel under the selected memory cell M24 is turned on and with high channel current if positive charges are stored in its charge-trapping layer. Therefore, the digital data stored in the selected memory cell M24 can be identified as “0” or “1” according to on/off state and channel current difference thereof.

Besides, with reference to FIG. 3C, while programming the memory cell M24, some electrons might be trapped into the charge-trapping layer near the source side of the memory cell M24. These electrons will cause disturbance to the memory cell M24. According to the read mode described above, a voltage of about 1.5V is applied to generate a depletion region so as to shield the electrons that causes disturbance to the memory cell M24. Thus, erroneous judgment of the memory cell M24 can be avoided.

With reference to FIGS. 2 and 3D, a first erasure mode of the present invention using hot hole injection is illustrated. While the selected memory cell M24 is to be erased, a voltage of about 4.5V is applied to the bit line BL2, and a voltage of about −5V is applied to the word line WL4 coupled to the selected memory cell M24. Meanwhile, a voltage of about 0V is applied to the unselected bit lines BL1 and BL3, a voltage of about 9V is applied to the unselected word lines WL1-WL3 disposed between the word line WL4 and the drain region D, and applied to the selecting line SG and a voltage of about 0V is applied to the unselected word lines WL5-WLn disposed between the word line WL4 and the source region S. Hot holes are then injected into the charge-trapping layer to erase the selected memory cell M24.

In the erasure method described above, hot-hole injection serves as an example to erase the memory cell. Alternatively, the present invention can erase the memory cell by FN tunneling method where voltage difference is formed between the gate and the substrate to pull the trapped electrons in the charge-trapping layer into the substrate.

With reference to FIGS. 2 and 3E, a second erasure mode of the present invention by FN tunneling is illustrated. While the memory cell M24 is to be erased, a voltage of about −12V is applied to the word lines WL1-WLn and a voltage of about 0V is applied to the substrate. Accordingly, the memory cell array is erased by FN tunneling.

With reference to FIGS. 2 and 3F, a third erasure mode of the present invention is illustrated. While the memory cell M24 is to be erased, a voltage of about 0V is applied to the word lines WL1-WLn and a voltage of about 12V is applied to the substrate, i.e. the P-well region. Accordingly, the memory cell array is erased by FN tunneling.

With reference to FIGS. 2 and 3G, a third erasure mode of the present invention is illustrated. While the memory cell M24 is to be erased, a voltage of about −6V is applied to the word lines WL1-WLn and a voltage of about 6V is applied to the substrate, i.e. the P-well region. Accordingly, the memory cell array is erased by FN tunneling.

Among these embodiments of erasing the memory cells by FN tunneling method, the erasure mode of applying 12V to the substrate can save more power. However, a well region, such as the P-well, should be formed in the substrate when a voltage is intended to apply to the substrate.

In the operating method of the non-volatile memory cell of the present invention, the SSI method is used to program the memory cells by a single bit of a single memory cell as a programming unit and the hot-hole injection method or the FN tunneling method is used to erase the memory cell. Accordingly, cell current during operation can be lowered due to high efficient injection of electrons. The operating speed of the memory cell is also improved. Due to the low electric current consumption, power-consumption of the whole chip thus decreases.

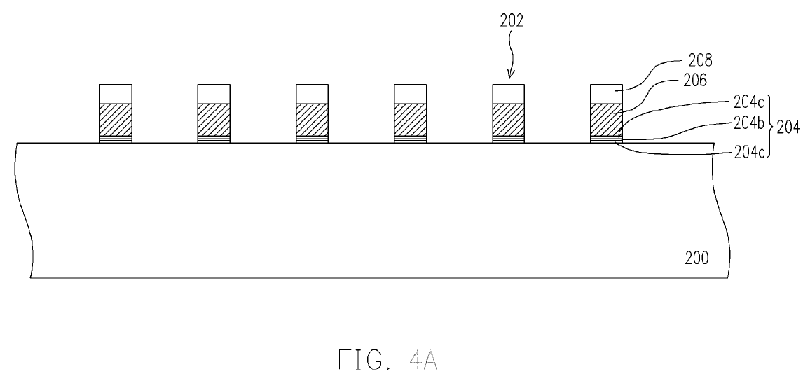

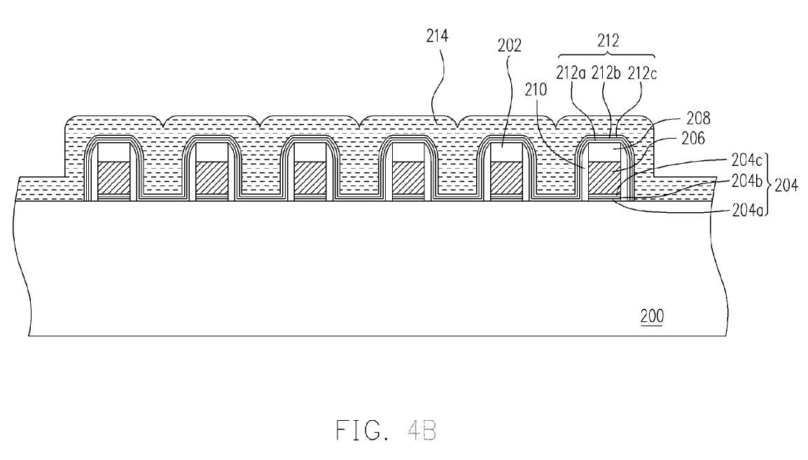

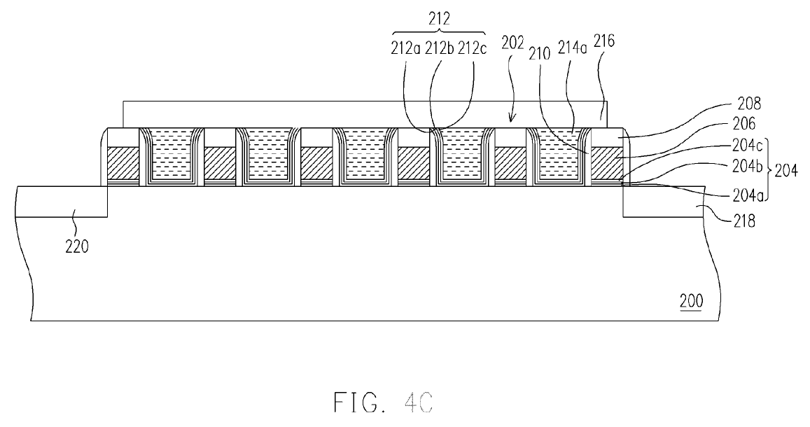

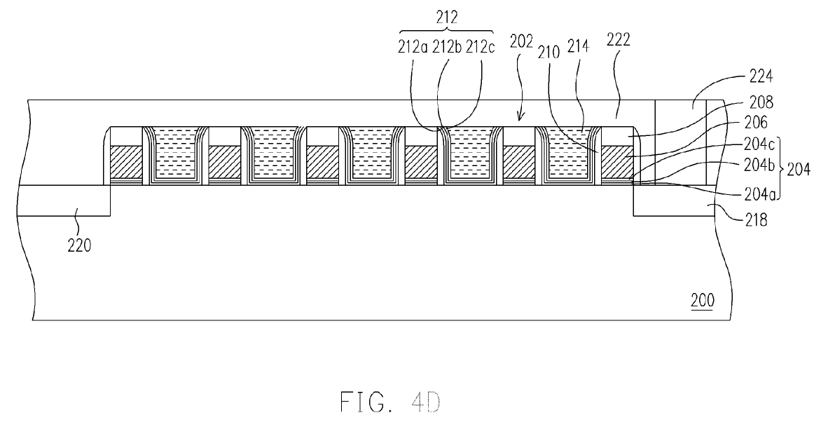

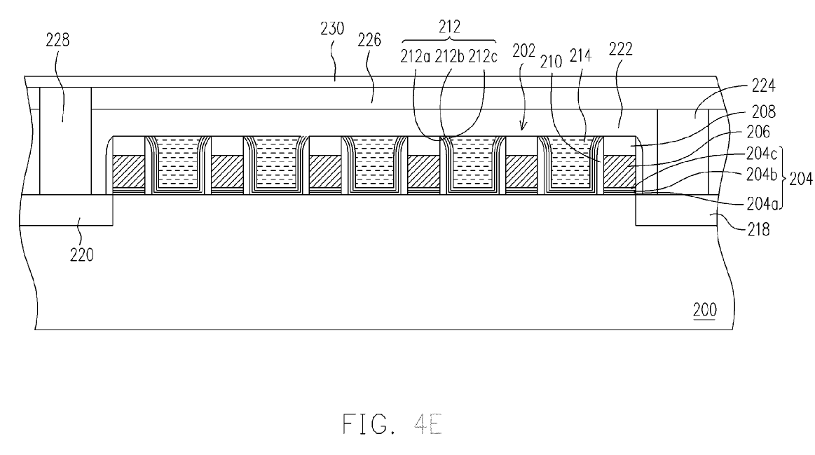

What follows is the description of an embodiment for fabricating the non-volatile memory of the present invention. FIGS. 4A-4E are cross-sectional drawings illustrating the manufacturing process of the non-volatile memory along A-A′ of FIG. 2A.

With reference to FIG. 4A, a substrate 200 is provided. The substrate can be, for example, a silicon substrate. The substrate 200 includes an isolation structure (not shown). A plurality of gate structures 202 is disposed over the substrate 200. The gate structure 202 includes a composite dielectric layer 204, a conductive layer 206(gate), and a cap layer 208. The method of fabricating the gate structure 202 includes, for example, sequentially deposing a composite dielectric material layer, a conductive material layer, and an isolation layer over the substrate 100. Then, a photolithographic process and an etch method are used to pattern these material layers to form the gate structures.

The composite dielectric layer 204 includes, for example, a bottom dielectric layer 204a, a charge-trapping layer 204b and a top dielectric layer 204c. The material of the bottom dielectric layer 204a can be silicon oxide. The silicon oxide layer can be formed by thermal oxidation, for example. The material of the charge-trapping layer 204b can be silicon nitride. The silicon nitride layer can be formed by chemical vapor deposition, for example. The material of the top dielectric layer 204c can be silicon oxide, which can be formed by chemical vapor deposition, for example. The bottom dielectric layer 204a and the top dielectric layer 204c also can be made of other materials. Similarly, the material of the charge-trapping layer 204b is not limited to silicon nitride. It can be other materials, such as tantalum oxide, strontium titanate or hafnium oxide that can trap charges.

The material of the conductive layer 206 can be doped polysilicon. The method of forming the conductive layer 206 includes, for example, depositing an undoped polysilicon layer by chemical vapor deposition and implanting ions into it.

The material of the cap layer 208 can be silicon oxide. The cap layer 208 can be formed by chemical vapor deposition using tetra ethyl ortho silicate (TEOS) and ozone (O₃) as reactive vapor source, for example.

With reference to FIG. 4B, insulation spacers 210 are formed on the sidewalls of the gate structures 202. The method of forming the insulation spacers 210 includes, for example, depositing an insulation material layer over the substrate and performing a self-align anisotropic etching process to form spacers on the sidewalls of the gate structures 202. The material of the insulation spacers 210 can be silicon nitride.

Next, another composite dielectric layer 212 is then formed over the substrate 200. The composite dielectric layer 212 includes, for example, a bottom dielectric layer 212a, a charge-trapping layer 212b and a top dielectric layer 212c. The material of the bottom dielectric layer 212a can be silicon oxide, which can be formed by thermal oxidation, for example. The material of the charge-trapping layer 212b can be silicon nitride, which can be formed by chemical vapor deposition, for example. The material of the top dielectric layer 212c can be silicon oxide, which can be formed by chemical vapor deposition, for example. The bottom dielectric layer 212a and the top dielectric layer 212c also can be made of other materials. The material of the charge-trapping layer 212b is not limited to silicon nitride. It can be other materials, such as tantalum oxide, strontium titanate or hafnium oxide that can trap charges.

Then, another conductive layer 214 is then formed over the substrate 200. The conductive layers 214 fill the gaps between neighboring gate structures 202. The material of the conductive layer 214 can be doped polysilicon. The method of forming the conductive layer 214 includes depositing an undoped polysilicon layer and implanting ions into the undoped polysilicon layer.

With reference to FIG. 4C, a portion of the conductive layer 214 is removed until the cap layer 208 is exposed. Thus, the conductive layers 214a are formed between the gate structures 202. Meanwhile, the composite dielectric layer 212 is formed as U-shape layers between the gate structures. The conductive layers 214a connect the gate structures 202 in series. The method of removing a portion of the conductive layer 214 includes, for example, an etch-back method or a chemical-mechanical polishing method. The conductive layer 214a and the composite dielectric layer 212 constitute another gate structure. Note that, in order to reduce the resistance of the conductive layer 214a, a metal silicide layer can be formed on the surface of the conductive layer 214a.

Then, a patterned mask layer 216 is then formed over the substrate 200, exposing the area where source/drain regions are to be formed. An etching process is performed to remove part of the conductive layer 214 and the composite dielectric layer 212 which cover the substrate for forming the source region and the drain region.

By using the patterned mask layer 216, an ion implantation process is performed to form the drain region 218 and the source region 220 in the substrate 200. The drain region 218 and the source region 220 are formed in the substrate 200 at the two sides of the connected gate structures 202 and the conductive layers 214a.

With reference to FIG. 4D, an interlayer dielectric layer 222 is formed over the substrate 200. The material of the interlayer dielectric layer 222 can be silicon oxide, which can be formed by chemical vapor deposition, for example. The source line 224 is formed in the interlayer dielectric layer 222 to connect with the source region 218. The material of the source line 224 can be tungsten.

With reference to FIG. 4E, another interlayer dielectric layer 226 is formed over the substrate 200. Plugs 228 are formed in the interlayer dielectric layer 226 to electrically connect with the drain region 228. The conductive line 230(bit line) is formed over the interlayer dielectric layer 226 to electrically connect with the plugs 228. The following steps for fabricating the non-volatile memory are known to persons skilled in the art. Thus, detailed descriptions are omitted.

In this embodiment, the composite dielectric layer 212 and the conductive layer 214a fill the gaps between the neighboring gate structures 202. Therefore, additional gate structures can be formed between the gate structures 202 without photolithographic and etching process. Thus, the method of the present invention is simpler and costs cheaper. Further, the present invention utilizes the charge-trapping layers 204b and 212b as charge-storing units, and therefore it is needless to concern about gate-coupling ratio. Furthermore, with low operating voltage, the operation speed of the memory of the present invention can be increased. Also, as comparing with conventional non-volatile memory manufacturing process, the method of the present invention is simpler and has lower manufacturing costs.

In this embodiment, a memory cell column with six memory cells is used as an example. The present invention, however, is not limited thereto. The numbers of cells in the memory cell column of the present invention can be modified if required. For example, a memory cell column may include 32 to 64 memory cells. Besides, the method of fabricating the non-volatile memory of the present invention can apply to fabricate a whole memory cell array.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A non-volatile memory unit, comprising:
a first memory cell disposed over a substrate, comprising:
a first gate disposed on the substrate; and
a first composite dielectric layer disposed between the first gate and the substrate, the first composite dielectric layer comprising a first bottom dielectric layer, a first charge-trapping layer and a first top dielectric layer;
a first insulation spacer disposed on a sidewall of the first memory cell; and
a second memory cell disposed over the substrate, adjacent to the first memory cell and separated therefrom by the first insulation spacer, the second memory cell comprising:
a second gate disposed over the substrate;
a second composite dielectric layer disposed between the second gate and the substrate, the second composite dielectric layer comprising a second bottom dielectric layer, a second charge-trapping layer and a second top dielectric layer.

2. The non-volatile memory unit of claim 1, wherein a material of the first and the second charge-trapping layers comprises silicon nitride.

3. The non-volatile memory unit of claim 1, wherein a material of the first bottom dielectric layer, the first top dielectric layer, the second bottom dielectric layer and the second top dielectric layer comprises silicon oxide.

4. The non-volatile memory unit of claim 1, wherein a material of the first insulation spacer comprises silicon oxide or silicon nitride.

5. The non-volatile memory unit of claim 1, wherein the first insulation spacer is formed by depositing an insulation layer over the first gate, and then performing a self-aligned etching process.

6. The non-volatile memory unit of claim 1, wherein the second composite layer is further disposed between the second gate and the first insulation spacer.

7. A non-volatile memory, comprising:
a cell column, constituted by a plurality of the non-volatile memory units of claim 1, wherein the non-volatile memory units are connected in series and separated by a plurality of second insulation spacers;
a selecting unit disposed on one side of the cell column, the selecting unit comprising:
a third gate;
a third composite dielectric layer disposed between the third gate and the substrate, the third composite dielectric layer comprising a third bottom dielectric layer, a third charge-trapping layer and a third top dielectric layer;
a third insulation spacer disposed on a sidewall of the selecting unit, wherein the third insulation spacer is disposed between the selecting unit and the cell column;
a source region disposed on the other side of the cell column; and
a drain region disposed in the substrate adjacent to the selecting unit.

8. The non-volatile memory of claim 7, wherein a material of the third charge-trapping layer comprises silicon nitride.

9. The non-volatile memory of claim 7, wherein a material of the third bottom dielectric layer and the third top dielectric layer comprises silicon oxide.

10. The non-volatile memory of claim 7, wherein the plurality of second insulation spacers comprise a material selected from the group consisting of silicon oxide and silicon nitride.

11. The non-volatile memory of claim 7, wherein the third insulation spacer comprises a material selected from the group consisting of silicon oxide and silicon nitride.

12. A non-volatile memory, comprising:
a memory cell array, wherein each column of the memory cell array includes a plurality of first memory cells and a plurality of second memory cells;
a plurality of selecting units, each disposed on one side of each column of the memory cell array respectively, wherein in each column the selecting unit and the plurality of first memory cells are arranged to form a plurality of gaps and each of the plurality of second memory cells stuffs up a different one of the gaps respectively;
a plurality of first doped regions, each disposed on the other side of each column of the memory cell array respectively;
a plurality of second doped regions, each disposed adjacent to each of the plurality of selecting units respectively;
a plurality of word lines;
a plurality of bit lines, wherein each intersection of the plurality of word lines and each of the plurality of bit lines is corresponding to a different one of the plurality of first memory cells or the plurality of second memory cells;
a plurality of selecting lines, each connected to a different row of the plurality of selecting units; and
a plurality of common lines, each connected to a different row of the plurality of first doped regions.

13. The non-volatile memory of claim 12, wherein each of the plurality of first memory cells comprising:
a first gate;
a first composite dielectric layer disposed under the first gate, including a first bottom dielectric layer, a first charge-trapping layer and a first top dielectric layer; and
a pair of first insulation spacers disposed on the sidewalls of the first gate; each of the plurality of second memory cells comprising:
a second gate; and
a second composite dielectric layer disposed under the second gate, the second composite dielectric layer comprising a second bottom dielectric layer, a second charge-trapping layer and a second top dielectric layer; and each of the plurality of selecting units comprising:
a select gate; and
a pair of second insulation spacers disposed on the side walls of the select gate.

14. The non-volatile memory of claim 13, wherein a material of the first and the second charge-trapping layers comprises silicon nitride.

15. The non-volatile memory of claim 13, wherein a material of the first bottom dielectric layer, the first top dielectric layer, the second bottom dielectric layer and the second top dielectric layer comprises silicon oxide.

16. The non-volatile memory of claim 13, wherein a material of the first insulation spacers and the second insulation spacers comprises silicon oxide or silicon nitride.

17. The non-volatile memory of claim 13, wherein each of the plurality of selecting units further comprises:
a third composite dielectric layer disposed under the select gate, the third composite dielectric layer comprising a third bottom dielectric layer, a third charge-trapping layer and a third top dielectric layer.

18. The non-volatile memory of claim 17, wherein a material of the third charge-trapping layer comprises silicon nitride.

19. The non-volatile memory of claim 17, wherein a material of the third bottom dielectric layer and the third top dielectric layer comprises silicon oxide.

20. The non-volatile memory of claim 12, wherein the plurality of first doped regions are n-type source regions.

21. The non-volatile memory of claim 12, wherein the plurality of second doped regions are n-type drain regions.

22. The non-volatile memory of claim 21, wherein each of the plurality of drain regions is connected to a different one of the plurality of bit lines respectively.

23. The non-volatile memory of claim 13, wherein each of the first gates of the plurality of first memory cells or the second gates of the plurality of second memory cells is connected to a different one of the plurality of word lines.

24. The non-volatile memory of claim 13, wherein the second composite dielectric layers of the plurality of second memory cells are formed as U-shape layers in the gaps and are stuffed up by the second gates of the plurality of second memory cells.

25. A non-volatile memory unit, comprising:
a first memory cell disposed on a substrate;
a selecting unit, disposed on the substrate and separated from the first memory cell by a gap;
a second memory cell stuffed into the gap;
a first insulation spacer, separating the first memory cell and the second memory cell; and
a second insulation spacer, separating the selecting unit and the second memory cell;
wherein the first memory cell comprises a first gate, the second memory cell comprises a second gate and the selecting unit comprises a third gate for turning on/off channel regions thereunder.

26. The non-volatile memory unit of claim 25, wherein the second memory cell further comprises a U-shape layer, which supports the second gate in the gap.

27. The non-volatile memory unit of claim 26, wherein the U-shape layer is a charge-tapping layer.

28. The non-volatile memory unit of claim 27, wherein the U-shape layer is made of silicon nitride.

29. The non-volatile memory unit of claim 26, wherein the U-shape layer is a composite layer which comprises a tunneling dielectric layer, a charge-trapping layer and a top dielectric layer.

30. The non-volatile memory unit of claim 29, wherein the tunneling dielectric layer is made of silicon oxide.

31. The non-volatile memory unit of claim 29, wherein the charge-trapping layer is made of silicon nitride.

32. The non-volatile memory unit of claim 29, wherein the top dielectric layer is made of silicon oxide.

33. The non-volatile memory unit of claim 25, wherein the first memory cell further comprises:
a first tunneling dielectric layer disposed on the substrate;
a first charge-trapping layer disposed on the first tunneling dielectric layer; and
a first top dielectric layer disposed on the charge-trapping layer.

34. The non-volatile memory unit of claim 33, wherein the first tunneling dielectric layer is made of silicon oxide.

35. The non-volatile memory unit of claim 33, wherein the first charge-trapping layer is made of silicon nitride.

36. The non-volatile memory unit of claim 33, wherein the first top dielectric layer is made of silicon oxide.

37. The non-volatile memory unit of claim 25, wherein the selecting unit further comprises a dummy charge trapping layer disposed between the third gate and the substrate.

38. The non-volatile memory unit of claim 37, wherein the first memory cell further comprises:
a first tunneling dielectric layer disposed on the substrate;
a first charge-trapping layer disposed on the first tunneling dielectric layer; and
a first top dielectric layer disposed on the charge-trapping layer.

39. The non-volatile memory unit of claim 38, wherein the selecting unit further comprises:
a second tunneling dielectric layer disposed between the dummy charge-trapping layer and the substrate; and
a second top dielectric layer disposed between the dummy charge-storage layer and the third gate.

40. The non-volatile memory unit of claim 37, wherein the second memory cell further comprises a U-shape layer.

41. The non-volatile memory unit of claim 40, wherein the U-shape layer is a composite layer which comprises at least a second charge-trapping layer.

42. The non-volatile memory unit of claim 41, wherein the second charge-trapping layer is made of silicon nitride.

43. The non-volatile memory unit of claim 41, wherein the U-shape layer further comprises:
a third tunneling dielectric layer disposed between the second charge-trapping layer and the substrate; and
a third top dielectric layer disposed between the second charge-trapping layer and the second gate.

44. An operating method for a non-volatile memory, the memory comprising: a memory cell array with each column including a plurality of first memory cells and a plurality of second memory cells; a plurality of selecting units, each disposed on one side of each column of the memory cell array respectively, wherein in each column the selecting unit and the plurality of first memory cells are arranged to form a plurality of gaps and each of the plurality of second memory cells stuffs up a different one of the gaps respectively; a plurality of source regions, each disposed on the other side of each column of the memory cell array respectively; a plurality of drain regions, each disposed adjacent to each of the plurality of selecting units respectively; a plurality of word lines; a plurality of bit lines, wherein each intersection of the plurality of word lines and each of the plurality of bit lines is corresponding to a different one of the plurality of first memory cells or the plurality of second memory cells; a plurality of selecting lines, each connected to a different row of the plurality of selecting units; and a plurality of common lines, each connected to a different row of the plurality of source regions; the method comprising:
while programming a selected memory cell, applying 0V to a selected bit line and applying a first voltage to unselected bit lines, applying a second voltage to a selected word line near a word line coupled to the selected memory cell and adjacent to the drain region, applying a third voltage to unselected word lines and the selecting line, and applying a fourth voltage to a source line to program the selected memory source by source-side injection method.

45. The operating method of claim 44, wherein the first voltage is about 3.3V, the second voltage is about 1.5V, the third voltage is about 9V and the fourth voltage is about 4.5V.

46. The operating method of claim 44, the method further comprising:
while reading the selected memory cell, applying 0V to the selected bit line, applying a fifth voltage to the unselected bit lines, applying a sixth voltage to the word line coupled to the selected memory cell, applying a seventh voltage to the unselected word lines and the selecting line, and applying an eighth voltage to the source line to read the selected memory cell.

47. The operating method of claim 46, wherein the fifth voltage is about 1.5V, the sixth voltage is about 1.5V, the seventh voltage is about 6V and the eighth voltage is about 1.5V.

48. The operating method of claim 44, further comprising:
while erasing the selected memory cell, applying a ninth voltage to the selected bit line, applying 0V to the unselected bit lines, applying a tenth voltage to the word line coupled to the selected memory cell, applying an eleventh voltage to the unselected word lines between the word line coupled to the selected memory cell and the drain region, and to the selecting line, applying 0V to the unselected word lines between the word line coupled to the selected memory cell and the source region to erase the selected memory by hot-hole injection method.

49. The operating method of claim 48, wherein the ninth voltage is about 4.5V, the tenth voltage is about −5V and the eleventh voltage is about 9V.

50. The operating method of claim 44, further comprising:
while erasing the selected memory cell, applying a twelfth voltage on the word lines and applying a thirteenth voltage to the substrate to erase the selected memory cell array by FN tunneling method.

51. The operating method of claim 50, wherein the twelfth voltage is about −12V and the thirteenth voltage is about 0V.

52. The operating method of claim 50, wherein the twelfth voltage is about 0V and the thirteenth voltage is about 12V.

53. The operating method of claim 50, wherein the twelfth voltage is about −6V and the thirteenth voltage is about 6V.

54. A method of fabricating a non-volatile memory, comprising:
providing a substrate;
forming a plurality of gate structures over the substrate, each of the gate structures comprising a first composite dielectric layer, a first gate, and a cap layer, wherein every two of the plurality of gate structures are separated by a gap;
forming insulation spacers on sidewalls of the gate structures;
forming a second composite dielectric layer over the substrate;
forming a conductive layer over the substrate;
removing a portion of the conductive layer to form a plurality of second gates in the gaps between the gate structures, the second gates and the gate structures constituting a memory cell column; and
forming a source region and a drain region in the substrate respectively adjacent to two sides of the memory cell column.

55. The fabricating method of claim 54, wherein each of the first and the second composite dielectric layers comprises a bottom dielectric layer, a charge-trapping layer and a top dielectric layer.

56. The fabricating method of claim 54, wherein the step of removing the portion of the conductive layer comprises a chemical-mechanical polishing method.

57. The fabricating method of claim 54, wherein the step of forming the source region and the drain region comprises an ion implantation method.

58. The fabricating method of claim 54, wherein the step of forming the insulation spacers on the sidewalls of the gate structures comprises:
depositing an insulation layer over the substrate; and
anisotropically etching the isolation layer to form the insulation spacers.
